(19) United States
(12) Patent Application Publication
(10) Pub. No.: US 2026/0324156 A1
(43) Pub. Date: Oct. 15, 2026

(54) SEMICONDUCTOR LIGHT-EMITTING DEVICE FOR PIXELS, AND DISPLAY DEVICE COMPRISING SAME

(71) Applicant: LG ELECTRONICS INC., Seoul (KR)

(72) Inventors: Sungjin PARK, Seoul (KR); Taein KWON, Seoul (KR); Sunghyun MOON, Seoul (KR); Myoungsoo KIM, Seoul (KR); Jungsub KIM, Seoul (KR)

(73) Assignee: LG ELECTRONICS INC., Seoul (KR)

(21) Appl. No.: 19/486,083

(22) PCT Filed: Jun. 2, 2023
(86) PCT No.: PCT/KR2023/007637

§ 371 Date: Nov. 20, 2025

(51) Int. Cl. H10H 29/39

(52) U.S. Cl. CPC H10H 29/39

(57) ABSTRACT

A pixel semiconductor according to an embodiment and a display device including the same may include a light emitting structure including a first conductivity-type semiconductor layer, an active layer, and a second conductivity-type semiconductor layer, a contact hole formed within the light emitting structure, the contact hole penetrating the second conductivity-type semiconductor layer and the active layer, thereby exposing a portion of the first conductivity-type semiconductor layer, a first contact layer formed within the contact hole and positioned at a level lower than the second conductivity-type semiconductor layer and a second contact layer formed over the light emitting structure and electrically connected to the second conductivity-type semiconductor layer.

### TECHNICAL FIELD

The embodiment relates to a semiconductor light emitting device for pixels and a display device including the same.

### BACKGROUND ART

Large-area displays include liquid crystal displays (LCDs), organic light emitting diode (OLED) displays, and micro-LED displays.

A micro-LED display uses micro-LEDs, semiconductor light emitting diodes with a diameter or cross-sectional area of 100 μm or less, as display devices.

Micro-LED displays utilize semiconductor light emitting diodes (micro-LEDs) as their display devices, offering superior performance in many characteristics, including contrast ratio, response speed, color reproducibility, viewing angle, brightness, resolution, lifespan, luminous efficacy, and luminance.

In particular, micro-LED displays offer the advantage of modular separation and assembly, allowing for flexible display size and resolution adjustments.

However, large-scale micro-LED displays require millions of micro-LEDs, posing technical problem in quickly and accurately transferring micro-LEDs onto the display panel.

Recently developed transfer technologies include the pick-and-place process, the laser lift-off method, and the self-assembly method.

Among these, the self-assembly method, in which semiconductor light emitting devices autonomously find their assembly positions within a fluid, is advantageous for implementing large-screen display devices.

Recently, U.S. Pat. No. 9,825,202 proposed a micro-LED structure suitable for self-assembly. However, research on manufacturing displays through self-assembly of micro-LEDs remains insufficient.

In particular, conventional technologies can improve transfer speed when rapidly transferring millions of semiconductor light emitting devices onto large displays. However, this can lead to a high transfer error rate, which in turn lowers transfer yield.

Meanwhile, self-assembly transfer processes using dielectrophoresis (DEP) have been attempted in related technologies. However, these technologies suffer from low self-assembly yields due to uneven DEP forces.

Meanwhile, the self-assembly method using internal technology's DEP force includes a step of first moving the LED chip to the assembly hole area using the magnetic force of a magnet, and a step of applying an alternating current to the assembly wiring to assemble the LED chip into the assembly hole using the DEP force.

However, since the LED chip consists of an n-type semiconductor layer and a p-type semiconductor layer on the top and bottom, and n-type electrodes and p-type electrodes are disposed respectively, it is very important to maintain the vertical orientation of the LED chip when assembling it into the assembly hole. This is because if the LED chip is assembled with the orientation tilted or even rotated 180 degrees, electrical short-circuit defects may occur during the subsequent wiring process.

However, internal research has shown that directional control of LED chips during self-assembly within a fluid is a challenging problem, and a solution is urgently needed.

Furthermore, related technologies suffer from a problem of reduced electrical contact between the electrodes of self-assembled LED chips and the panel electrodes, resulting in a reduced lighting rate.

Furthermore, semiconductor light emitting devices that emit R, G, and B colors have different chip shapes and electrode locations, resulting in a reduced assembly rate and increased process time during simultaneous assembly.

Furthermore, the assembly rate is uneven, depending on the location of the semiconductor contact area, the behavioral characteristics of the chip, or the shape of the chip.

### DISCLOSURE

### Technical Problem

One of the technical objects of the embodiment is to improve the luminous efficiency of a pixel semiconductor light emitting device and a display device including the same.

Another technical object of the embodiment is to improve the assembly rate of the pixel semiconductor light emitting device.

Another technical object of the embodiment is to improve the uniformity of the assembly force of the semiconductor light emitting device.

Another technical object of the embodiment is to reduce the difficulty and time of the display process even when the external shape of the semiconductor light emitting device varies.

Furthermore, one of the technical objects of the embodiment is to prevent misalignment of semiconductor light emitting devices during self-assembly.

Furthermore, one of the technical objects of the embodiment is to utilize assembly wiring as pixel wiring.

Furthermore, one of the technical objects of the embodiment is to improve the reliability of panel wiring connections in a display device.

The technical objects of the embodiment are not limited to those described in this section, but include those that can be understood through the description of the invention.

### Technical Solution

A pixel semiconductor according to an embodiment and a display device including the same may include a light emitting structure including a first conductivity-type semiconductor layer, an active layer, and a second conductivity-type semiconductor layer, a contact hole formed within the light emitting structure, the contact hole penetrating the second conductivity-type semiconductor layer and the active layer, thereby exposing a portion of the first conductivity-type semiconductor layer, a first contact layer formed within the contact hole and positioned at a level lower than the second conductivity-type semiconductor layer and a second contact layer formed over the light emitting structure and electrically connected to the second conductivity-type semiconductor layer.

Furthermore, in an embodiment, the contact hole may Furthermore include an opening extending in a horizontal direction.

Furthermore, in an embodiment, the opening may include a plurality of openings.

Furthermore, in an embodiment, the light emitting structure may have a plurality of light emitting areas by the plurality of openings.

Furthermore, in an embodiment, the first contact layer may include a magnetic layer.

Furthermore, in an embodiment, the first contact layer may be positioned at the center of the light emitting structure.

Furthermore, in an embodiment, the second contact layer may include a plurality of layers, The plurality of second contact layers may be disposed symmetrically with respect to the first contact layer.

Furthermore, in an embodiment, the light emitting structure may be circular.

Furthermore, in an embodiment, the light emitting structure may be oval.

Furthermore, a display device including a semiconductor light emitting device for pixels according to an embodiment includes a substrate, a plurality of assembly wirings spaced apart from each other on the substrate, a partition wall disposed on the plurality of assembly wirings and having an assembly hole, and a semiconductor light emitting device disposed in the assembly hole, the semiconductor light emitting device includes a light emitting structure including a first conductivity-type semiconductor layer, an active layer, and a second conductivity-type semiconductor layer, a contact hole disposed within the light emitting structure; a first contact layer disposed within the contact hole, a second contact layer disposed on the light emitting structure, and an opening extending from the contact hole to the exterior of the light emitting structure, and the first contact layer may be electrically connected to the assembly wiring through the opening.

### Advantageous Effects

The pixel semiconductor light emitting device according to the embodiment and the display device including the same have the technical effect of improving the light emitting efficiency.

For example, the embodiment can improve the light emitting efficiency by forming the first contact layer within the contact hole in a horizontal semiconductor light emitting device to increase the area of the light emitting area.

Furthermore, the embodiment has the technical effect of improving the assembly rate of the pixel semiconductor light emitting device.

For example, the embodiment can dispose the first contact layer including the magnetic layer at the center of the semiconductor light emitting device to concentrate the center of gravity at the center of the semiconductor light emitting device and prevent the semiconductor light emitting device from being biased during self-assembly.

For example, the embodiment can improve the balance of the semiconductor light emitting device within the fluid by symmetrically disposing the first opening and the second opening with respect to the first contact layer. Accordingly, the phenomenon of the light emitting device tilting or flipping in the fluid can be prevented, thereby providing the technical effect of improving the assembly rate.

Furthermore, the embodiment has a technical effect of ensuring uniform assembly force of semiconductor light emitting devices during self-assembly.

For example, the embodiment has a structure in which the first contact layer is located at the center of the semiconductor light emitting device and the second contact layer is located at the periphery, even if the external shapes of circular and oval semiconductor light emitting devices are different, thereby ensuring uniform assembly force.

Furthermore, the embodiment has the technical effect of improving the reliability of panel wiring connections in a display device.

For example, the embodiment can improve the reliability of panel wiring connections by connecting the first contact layer to the first electrode in both directions.

Furthermore, the embodiment has the technical effect of reducing the difficulty and process time of the wiring process by performing the panel wiring process in the same manner even when the external appearance of the semiconductor light emitting device is different.

Furthermore, the embodiment has a technical effect of uniformly controlling the behavioral characteristics of semiconductor light emitting devices during self-assembly in a fluid.

The technical effects of the embodiment are not limited to those described in this section, but include those that can be understood through the description of the invention.

### DESCRIPTION OF DRAWINGS

FIG. 1 is an exemplary diagram illustrating a living room of a house in which a display device according to an embodiment is disposed.

FIG. 2 is a block diagram schematically illustrating a display device according to an embodiment.

FIG. 3 is a circuit diagram illustrating an example of the pixels of FIG. 2.

FIG. 4 is an enlarged view of the first panel area of the display device of FIG. 1.

FIG. 5 is a cross-sectional view taken along line B1-B2 of area A2 of FIG. 4.

FIG. 6 is an exemplary diagram illustrating a light emitting device according to an embodiment assembled onto a substrate using a self-assembly method.

FIGS. 7 and 8 are perspective views of a semiconductor light emitting device being internally studied.

FIG. 9 is a perspective view of a semiconductor light emitting device according to a first embodiment.

FIG. 10 is a perspective view of a semiconductor light emitting device according to a second embodiment.

FIGS. 11 and 12 are perspective views of a semiconductor light emitting device being internally studied.

FIG. 13 is a perspective view of a semiconductor light emitting device according to a third embodiment.

FIG. 14 is a perspective view of a semiconductor light emitting device according to a fourth embodiment.

FIG. 15 is a conceptual diagram illustrating electrode connections of a semiconductor light emitting device according to an embodiment.

FIG. 16 is a cross-sectional view of a display device in which a semiconductor light emitting device according to an embodiment is assembled.

### MODE FOR INVENTION

Hereinafter, the embodiments disclosed in the present specification will be described in detail with reference to the attached drawings. The suffixes ‘module’ and ‘part’ used for components in the following description are given or used interchangeably in consideration of the ease of writing the specification, and do not have distinct meanings or roles in themselves. Also, the attached drawings are provided to facilitate the understanding of the embodiments disclosed in the present specification, and the technical ideas disclosed in the present specification are not limited by the attached drawings. Also, when an element such as a layer, area, or substrate is referred to as existing ‘on’ another element, this includes that it may be directly on the other element, or that other intermediate elements may exist therebetween.

The display devices described herein may include digital TVs, mobile phones, smart phones, laptop computers, digital broadcasting terminals, personal digital assistants (PDAs), portable multimedia players (PMPs), navigation systems, slate PCs, tablet PCs, Ultrabooks, desktop computers, and the like. However, the configurations according to the embodiments described herein may also be applied to devices capable of displaying, even if they are new product types developed in the future.

A light emitting device according to an embodiment and a display device including the same are described below.

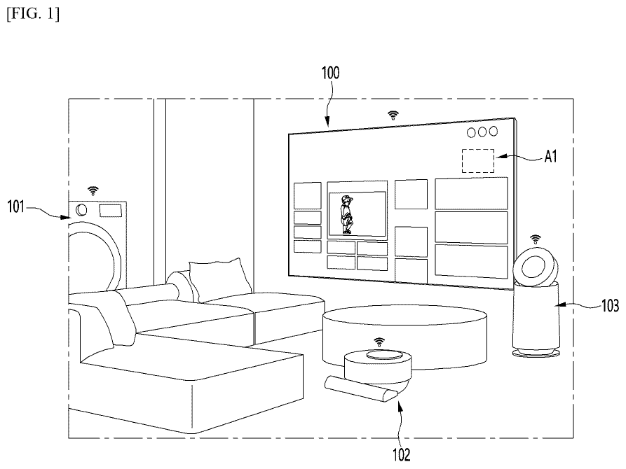

FIG. 1 illustrates a living room of a house in which a display device 100 according to an embodiment is placed.

The display device 100 according to the embodiment can display the status of various electronic products, such as a washing machine 101, a robot vacuum cleaner 102, and an air purifier 103, communicate with each electronic product based on IoT, and control each electronic product based on user setting data.

The display device 100 according to the embodiment can include a flexible display manufactured on a thin and flexible substrate. The flexible display can be bent or rolled like paper, while maintaining the characteristics of a conventional flat panel display.

In a flexible display, visual information can be realized by independently controlling the light emission of unit pixels disposed in a matrix. A unit pixel refers to the smallest unit for expressing a single color. The unit pixels of a flexible display can be realized by light emitting devices. In an embodiment, the light emitting devices may be micro-LEDs or nano-LEDs, but are not limited thereto.

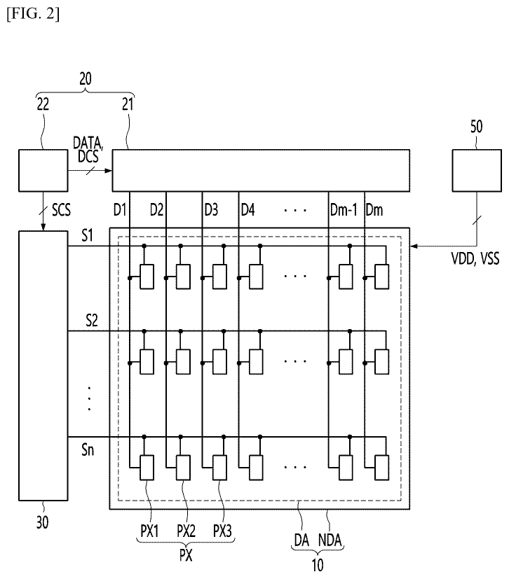

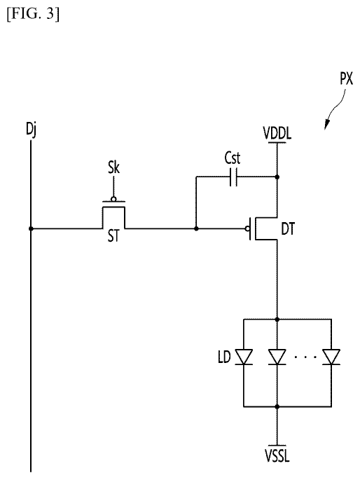

FIG. 2 is a block diagram schematically illustrating a display device according to an embodiment, and FIG. 3 is a circuit diagram illustrating an example of the pixels of FIG. 2.

Referring to FIGS. 2 and 3, a display device according to an embodiment may include a display panel 10, a driving circuit 20, a scan driving unit (30), and a power supply circuit (50).

The display device 100 according to the embodiment may drive a light emitting device using an active matrix (AM) method or a passive matrix (PM) method.

The driving circuit 20 may include a data driving unit 21 and a timing control unit 22.

The display panel 10 may be divided into a display area (DA) and a non-display area (NDA) disposed around the display area (DA). The display area (DA) is an area where pixels (PX) are formed to display an image. The display panel 10 may include data lines (D1 to Dm, m is an integer greater than or equal to 2), scan lines (S1 to Sn, n is an integer greater than or equal to 2) intersecting the data lines (D1 to Dm), a high-potential voltage line to which a high-potential voltage is supplied, a low-potential voltage line to which a low-potential voltage is supplied, and pixels (PX) connected to the data lines (D1 to Dm) and the scan lines (S1 to Sn).

Each of the pixels (PX) may include a first sub-pixel (PX1), a second sub-pixel (PX2), and a third sub-pixel (PX3). The first sub-pixel (PX1) may emit a first color light of a first wavelength, the second sub-pixel (PX2) may emit a second color light of a second wavelength, and the third sub-pixel (PX3) may emit a third color light of a third wavelength. The first color light may be red light, the second color light may be green light, and the third color light may be blue light, but the present invention is not limited thereto. Also, although FIG. 2 illustrates that each of the pixels (PX) includes three sub-pixels, the present invention is not limited thereto. That is, each of the pixels (PX) may include four or more sub-pixels.

Each of the first sub-pixel (PX1), the second sub-pixel (PX2), and the third sub-pixel (PX3) may be connected to at least one of the data lines (D1 to Dm), at least one of the scan lines (S1 to Sn), and a high-potential voltage line. The first sub-pixel (PX1) may include light emitting devices (LD), a plurality of transistors for supplying current to the light emitting devices (LD), and at least one capacitor (Cst), as shown in FIG. 3.

Although not illustrated in the drawing, each of the first sub-pixel (PX1), the second sub-pixel (PX2), and the third sub-pixel (PX3) may include only one light emitting device (LD) and at least one capacitor (Cst).

Each of the light emitting devices (LD) may be a semiconductor light emitting diode including a first electrode, a plurality of conductivity-type semiconductor layers, and a second electrode. Here, the first electrode may be an anode electrode, and the second electrode may be a cathode electrode, but this is not limited thereto.

Referring to FIG. 3, the plurality of transistors may include a driving transistor (DT) that supplies current to light emitting devices (LD), and a scan transistor (ST) that supplies a data voltage to the gate electrode of the driving transistor (DT). The driving transistor (DT) may include a gate electrode connected to the source electrode of the scan transistor (ST), a source electrode connected to a high-potential voltage line to which a high-potential voltage is applied, and a drain electrode connected to the first electrodes of the light emitting devices (LD). The scan transistor (ST) may include a gate electrode connected to a scan line (Sk, where k is an integer satisfying 1≤k≤n), a source electrode connected to the gate electrode of the driving transistor (DT), and a drain electrode connected to a data line (Dj, where j is an integer satisfying 1≤j≤m).

A capacitor (Cst) is formed between the gate electrode and the source electrode of the driving transistor (DT). The storage capacitor (Cst) may store a difference between the gate voltage and the source voltage of the driving transistor (DT).

The driving transistor (DT) and the scan transistor (ST) may be formed as thin film transistors. Also, although FIG. 3 mainly describes the driving transistor (DT) and the scan transistor (ST) as being formed as P-type MOSFETs (Metal Oxide Semiconductor Field Effect Transistors), the present invention is not limited thereto. The driving transistor (DT) and the scan transistor (ST) may also be formed as N-type MOSFETs. In this case, the positions of the source electrodes and the drain electrodes of each of the driving transistor (DT) and the scan transistor (ST) may be changed.

Also, FIG. 3 exemplifies the case where each of the first sub-pixel (PX1), the second sub-pixel (PX2), and the third sub-pixel (PX3) includes a 2T1C (2 Transistors 1 capacitor) having one driving transistor (DT), one scan transistor (ST), and one capacitor (Cst), the present invention is not limited thereto. Each of the first sub-pixel (PX1), the second sub-pixel (PX2), and the third sub-pixel (PX3) may include a plurality of scan transistors (ST) and a plurality of capacitors (Cst).

Referring again to FIG. 2, the driving circuit 20 outputs signals and voltages for driving the display panel 10. For this purpose, the driving circuit 20 may include a data driving unit 21 and a timing control unit 22.

The data driving unit 21 receives digital video data (DATA) and a source control signal (DCS) from the timing control unit 22. The data driving unit 21 converts the digital video data (DATA) into analog data voltages according to the source control signal (DCS) and supplies the converted data to the data lines (D1 to Dm) of the display panel 10.

The timing control unit 22 receives digital video data (DATA) and timing signals from the host system. The timing signals may include a vertical sync signal, a horizontal sync signal, a data enable signal, and a dot clock. The host system may be an application processor in a smartphone or tablet PC, a system-on-chip in a monitor, or a TV.

The scan driver (30) receives a scan control signal (SCS) from the timing controller 22. The scan driver (30) generates scan signals according to the scan control signal (SCS) and supplies them to the scan lines (S1 to Sn) of the display panel 10. The scan driver (30) may include a plurality of transistors and may be formed in a non-display area (NDA) of the display panel 10. Alternatively, the scan driver (30) may be formed as an integrated circuit, in which case it may be mounted on a gate flexible film attached to the other side of the display panel 10.

The power supply circuit (50) may generate a high-potential voltage (VDD) and a low-potential voltage (VSS) for driving the light emitting devices (LD) of the display panel 10 from the main power source and supply them to the high-potential voltage line and the low-potential voltage line of the display panel 10. Additionally, the power supply circuit (50) can generate and supply driving voltages for driving the driving circuit 20 and the scan driving unit (30) from the main power source.

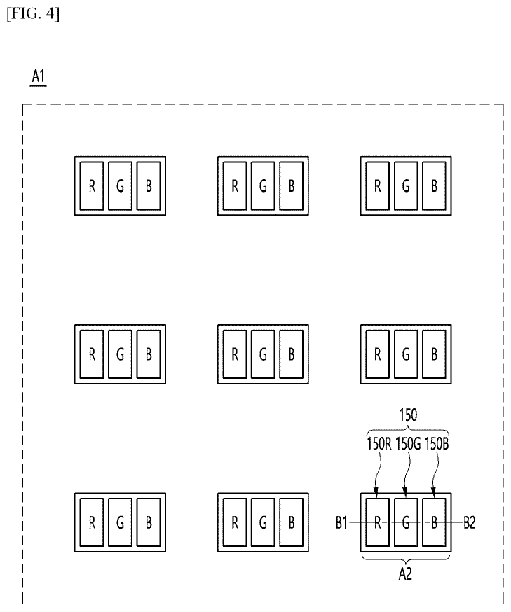

FIG. 4 is an enlarged view of the first panel area (A1) in the display device of FIG. 1.

According to FIG. 4, the display device 100 of the embodiment may be manufactured by mechanically and electrically connecting a plurality of panel areas, such as the first panel area (A1), through tiling.

The first panel area (A1) can include a plurality of light emitting devices 150 disposed for each unit pixel (PX of FIG. 2).

For example, a unit pixel (PX) may include a first sub-pixel (PX1), a second sub-pixel (PX2), and a third sub-pixel (PX3). For example, a plurality of red light emitting devices 150R may be disposed in the first sub-pixel (PX1), a plurality of green light emitting devices 150G may be disposed in the second sub-pixel (PX2), and a plurality of blue light emitting devices 150B may be disposed in the third sub-pixel (PX3). The unit pixel (PX) may further include a fourth sub-pixel in which no light emitting device is disposed, but this is not limited thereto. Meanwhile, the light emitting device 150 may be a semiconductor light emitting device.

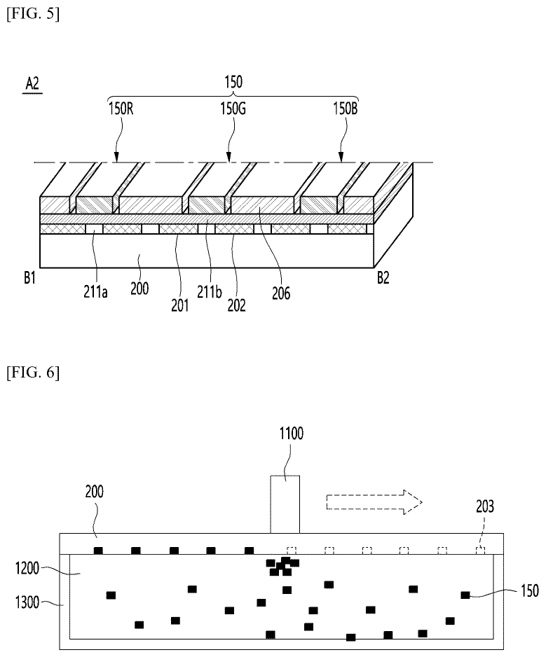

Next, FIG. 5 is a cross-sectional view taken along line B1-B2 of area A2 of FIG. 4.

Referring to FIG. 5, the display device 100 of the embodiment may include a substrate 200, assembly wiring 201, 202, a first insulating layer 211a, a second insulating layer 211b, a third insulating layer 206, and a plurality of light emitting devices 150.

The assembly wiring may include a first assembly wiring 201 and a second assembly wiring 202 that are spaced apart from each other. The first assembly wiring 201 and the second assembly wiring 202 may be provided to generate a dielectrophoretic force for assembling the light emitting device 150. Also, the first assembly wiring 201 and the second assembly wiring 202 may be electrically connected to the electrodes of the light emitting device and function as electrodes of the display panel.

The assembly wiring 201, 202 may be formed of a light-transmitting electrode (ITO) or may include a metal material having excellent electrical conductivity. For example, the assembly wiring 201, 202 may be formed of at least one of titanium (Ti), chromium (Cr), nickel (Ni), aluminum (Al), platinum (Pt), gold (Au), tungsten (W), and molybdenum (Mo), or an alloy thereof.

A first insulating layer 211a may be disposed between the first assembly wiring 201 and the second assembly wiring 202, and a second insulating layer 211b may be disposed on the first assembly wiring 201 and the second assembly wiring 202). The first insulating layer 211a and the second insulating layer 211b may be an oxide film, a nitride film, or the like, but are not limited thereto.

The light emitting device 150 may include a red light emitting device 150, a green light emitting device 150G, and a blue light emitting device 150B to form a unit pixel (sub-pixel), but are not limited thereto. A red phosphor, a green phosphor, or the like may be provided to implement red and green, respectively.

The substrate 200 may be formed of glass or polyimide. Also, the substrate 200 may include a flexible material such as polyethylene naphthalate (PEN) or polyethylene terephthalate (PET). Also, the substrate 200 may be a light-transmitting material, but is not limited thereto.

The third insulating layer 206 may include an insulating and flexible material such as polyimide, PEN, PET, etc., and may be formed integrally with the substrate 200 to form a single substrate.

The third insulating layer 206 may be a conductive adhesive layer having adhesive properties and conductivity, and the conductive adhesive layer may be flexible to enable a flexible function of the display device. For example, the third insulating layer 206 may be a conductive adhesive layer such as an anisotropic conductive film (ACF), an anisotropic conductive medium, or a solution containing conductive particles. The conductive adhesive layer may be a layer that is electrically conductive in a direction vertical to the thickness, but electrically insulating in a direction horizontal to the thickness.

The third insulating layer 206 may include an assembly hole 203 into which a light emitting device 150 is inserted (see FIG. 6). Therefore, during self-assembly, the light emitting device 150 can be easily inserted into the assembly hole 203 of the third insulating layer 206. The assembly hole 203 may be referred to as an insertion hole, a fixing hole, an alignment hole, etc.

The gap between the assembly wirings 201, 202 is formed to be smaller than the width of the light emitting device 150 and the width of the assembly hole 203, so that the assembly position of the light emitting device 150 can be more precisely fixed using an electric field.

A third insulating layer 206 is formed on the assembly wirings 201, 202, thereby protecting the assembly wirings 201, 202 from the fluid 1200 and preventing leakage of current flowing through the assembly wirings 201, 202. The third insulating layer 206 may be formed as a single layer or multiple layers of an inorganic insulator such as silica or alumina, or an organic insulator.

Also, the third insulating layer 206 may include an insulating and flexible material such as polyimide, PEN, PET, etc., and may be formed integrally with the substrate 200 to form a single substrate.

The third insulating layer 206 may be an adhesive insulating layer or a conductive adhesive layer. The third insulating layer 206 may be flexible, enabling the display device to function as a flexible device.

The third insulating layer 206 may have a partition wall, and an assembly hole 203 may be formed by the partition wall. For example, when forming the substrate 200, a portion of the third insulating layer 206 may be removed, allowing each of the light emitting devices 150 to be assembled into the assembly hole 203 of the third insulating layer 206.

The substrate 200 has an assembly hole 203 formed therein, into which the light emitting devices 150 are coupled, and the surface on which the assembly hole 203 is formed may be in contact with the fluid 1200. The assembly hole 203 can guide the exact assembly position of the light emitting device 150.

Meanwhile, the assembly hole 203 may have a shape and size corresponding to the shape of the light emitting device 150 to be assembled at the corresponding position. Accordingly, it is possible to prevent another light emitting device from being assembled in the assembly hole 203 or multiple light emitting devices from being assembled.

FIG. 6 is a drawing illustrating an example of a light emitting device according to an embodiment being assembled on a substrate by a self-assembly method, and the self-assembly method of the light emitting device will be described with reference to the drawings.

The substrate 200 may be a panel substrate of a display device. In the following description, the substrate 200 is described as being a panel substrate of a display device, but the present invention is not limited thereto.

Referring to FIG. 6, a plurality of light emitting devices 150 may be placed in a chamber 1300 filled with a fluid 1200. The fluid 1200 may be water, such as ultrapure water, but is not limited thereto. The chamber may be referred to as a tank, container, vessel, or the like.

Thereafter, the substrate 200 may be placed on the chamber 1300. Depending on the embodiment, the substrate 200 may also be placed into the chamber 1300.

As illustrated in FIG. 5, a pair of assembly wirings 201, 202 corresponding to each light emitting device 150 to be assembled may be disposed on the substrate 200.

Referring to FIG. 6, after the substrate 200 is disposed, an assembly device 1100 including a magnetic body may move along the substrate 200. For example, a magnet or an electromagnet may be used as the magnetic body. The assembly device 1100 may move in contact with the substrate 200 to maximize the area affected by the magnetic field within the fluid 1200. Depending on the embodiment, the assembly device 1100 may include a plurality of magnetic bodies or may include magnetic bodies of a size corresponding to that of the substrate 200. In this case, the movement distance of the assembly device 1100 may be limited within a predetermined range.

The light emitting device 150 within the chamber 1300 can move toward the assembly device 1100 by the magnetic field generated by the assembly device 1100.

While moving toward the assembly device 1100, the light emitting device 150 can enter the assembly hole 203 and come into contact with the substrate 200 by the dielectrophoretic force (DEP).

Specifically, the assembly wirings 201, 202 form an electric field by an externally supplied power source, and a dielectrophoretic force may be formed between the assembly wirings 201, 202 by this electric field. The light emitting device 150 may be fixed to the assembly hole 203 on the substrate 200 by this dielectrophoretic force.

The light emitting device 150 in contact with the substrate 200 may be prevented from being detached by the movement of the assembly device 1100 due to the electric field applied by the assembly wiring 201, 202 formed on the substrate 200. According to an embodiment, the time required for each of the light emitting devices 150 to be assembled on the substrate 200 may be drastically shortened by the self-assembly method using the above-described electromagnetic field, so that a large-area, high-pixel display may be implemented more quickly and economically.

At this time, a predetermined solder layer (not shown) is formed between the light emitting device 150 assembled on the assembly hole 203 of the substrate 200 and the assembly electrode, thereby improving the bonding strength of the light emitting device 150.

Next, a molding layer (not shown) may be formed in the assembly hole 203 of the substrate 200. The molding layer may be a light-transmitting resin or a resin containing a reflective material or a scattering material.

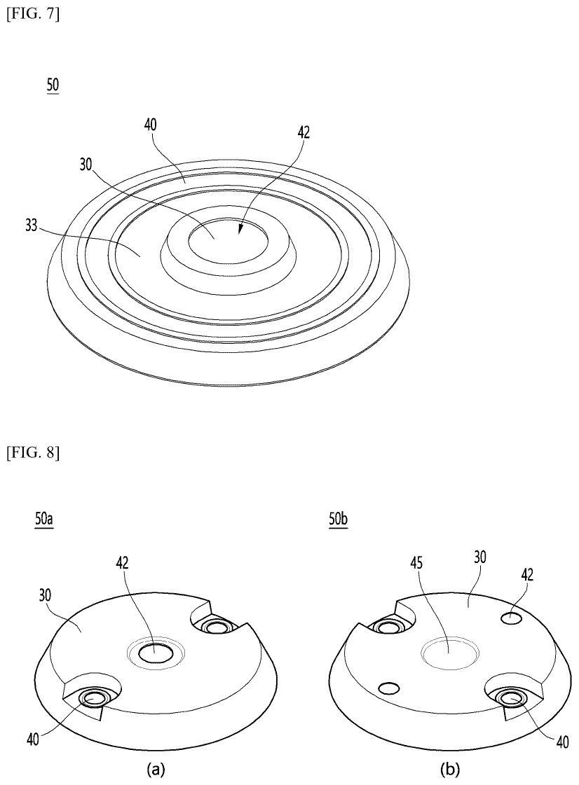

FIGS. 7 and 8 are perspective views of a pixel semiconductor light emitting device being studied in the internal technology. Referring to FIG. 7, the semiconductor light emitting device 50 being studied internally may include a light emitting area 30, a passivation layer 33, and a first contact layer 40. An n-electrode and a p-electrode are connected to the upper surface of the semiconductor light emitting device, and the upper surface is covered by the passivation layer 33 except for the portion connected to the electrodes.

The light emitting area 30 is positioned at the center of the semiconductor light emitting device, and a first contact layer 40 may be disposed to surround the light emitting area 30. Also, a second contact layer 42 may be disposed on the light emitting area 30. Also, the first contact layer 40 may include a magnetic layer. The magnetic layer may function to move the semiconductor light emitting device toward the panel substrate when assembling the semiconductor light emitting device.

Meanwhile, due to the ring-shaped first contact layer 40 surrounding the light emitting area 30, the area occupied by the light emitting area 30 on the upper surface of the semiconductor light emitting device may become smaller, resulting in a problem of reduced light emitting efficiency.

Referring to FIG. 8a, the semiconductor light emitting device 50a may have a light emitting area 30 on the upper surface thereof, and a second contact layer 42 may be disposed at the center of the light emitting area 30. Also, a portion of the light emitting area 30 may be etched to expose a semiconductor layer, and a first contact layer 40 may be disposed on the semiconductor layer. The semiconductor light emitting device 50a may emit light when power is connected to each of the first contact layer 40 and the second contact layer 42.

Also, referring to FIG. 8b, a magnetic layer (not shown) may be disposed at the center of the light emitting area 30 of the semiconductor light emitting device 50b. The magnetic layer may function to allow the semiconductor light emitting device to move to the assembly substrate by magnetic force during self-assembly of the semiconductor light emitting device. A passivation layer 45 may be disposed on the magnetic layer (not shown). Since the magnetic layer is not used for electrical connection in the panel process, it may be covered and protected by the passivation layer 45. Also, the first contact layer 40 may be disposed in an area where the light emitting area is partially etched. Also, the second contact layer 42 may be disposed in an outer area of the upper surface of the light emitting area.

Meanwhile, the semiconductor light emitting devices 50a, 50b of FIGS. 8a and 8b have different contact layer locations when forming wiring for power supply, which makes the panel process cumbersome, and if the contact layer for the n-type contact is located on the outside, there is a problem of unevenness during assembly.

Hereinafter, the technical features of an embodiment for solving the above problems will be described.

### First Embodiment

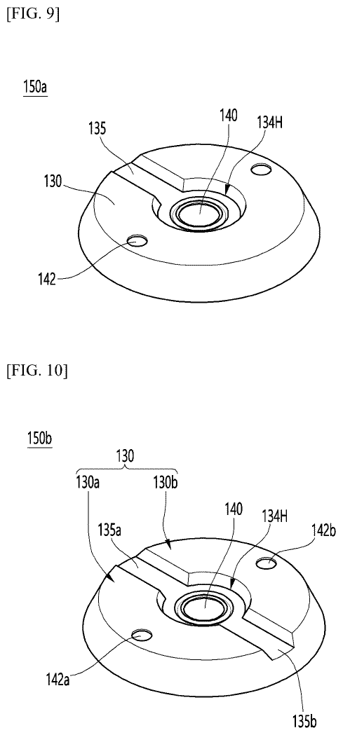

FIG. 9 is a perspective view illustrating a semiconductor light emitting device for a pixel according to an embodiment. Referring to FIG. 9, the semiconductor light emitting device 150a of the embodiment may be circular. The semiconductor light emitting device 150a of the embodiment may be a semiconductor light emitting device that emits red light, but is not limited thereto. Also, the semiconductor light emitting device according to the embodiment may have a structure of a horizontal semiconductor light emitting device, but is not limited thereto.

A pixel semiconductor light emitting device 150a according to an embodiment may include a first conductivity-type semiconductor layer, an active layer, a second conductivity-type semiconductor layer, a passivation layer, a first contact layer, a second contact layer, an opening, and a contact hole.

The first conductivity-type semiconductor layer may be an n-type semiconductor layer, and the second conductivity-type semiconductor layer may be a p-type semiconductor layer, but is not limited thereto. The first conductivity-type semiconductor layer, the active layer, and the second conductivity-type semiconductor layer may be formed of a compound semiconductor material. For example, the compound semiconductor material may be a group III-V compound semiconductor material, a group II-VI compound material, etc. For example, the compound semiconductor may be a binary compound selected from the group consisting of GaP, GaAs, GaSb, AlP, AlAs, AlSb, InP, InAs, InSb, and mixtures thereof, a ternary compound selected from the group consisting of GaNP, GaNAs, GaNSb, GaPAs, GaPSb, AlInP, AlNP, AlNAs, AlNSb, AlPAs, AlPSb, InNP, InNAs, InNSb, InPAs, InPSb, GaAlNP and mixtures thereof, and a quaternary compound selected from the group consisting of AlGaInP, GaAlNAs, GaAlNSb, GaAlPAs, GaAlPSb, GaInNP, GaInNAs, GaInNSb, GalnPAs, GaInPSb, InAlNP, InAlNAs, InAlNSb, InAlPAs, InAlPSb and mixtures thereof.

For example, the first conductivity-type semiconductor layer may include a first conductive dopant, and the second conductivity-type semiconductor layer 133 may include a second conductive dopant. For example, the first conductive dopant may be an n-type dopant, such as silicon (Si), and the second conductive dopant may be a p-type dopant, such as boron (B).

The active layer is a region that generates light and may generate light having a specific wavelength band depending on the material properties of the compound semiconductor. Also, the active layer may have a multiple quantum well or single quantum well structure, and the wavelength band may be determined by the energy bandgap of the compound semiconductor included in the active layer. Therefore, the semiconductor light emitting device of the embodiment may generate UV light, blue light, green light, and red light depending on the energy bandgap of the compound semiconductor included in the active layer.

Also, the first contact layer 140 may be an n-type contact layer, and the second contact layer 142 may be a p-type contact layer, but is not limited thereto.

In the embodiment, the upper region of the pixel semiconductor light emitting device 150a may be a light emitting area 130. The light emitting area 130 may be a region where light generated from an active layer (not shown) is emitted to the outside. Meanwhile, a contact hole 134H may be formed within the light emitting area 130. The contact hole 134H may be formed at the center of the semiconductor light emitting device. Also, the contact hole 134H may include an opening 135 extending horizontally and connected to the outside of the semiconductor light emitting device.

Meanwhile, a first conductivity-type semiconductor layer (not shown) may be exposed within the contact hole 134H. A first contact layer 140 may be disposed on the exposed first conductivity-type semiconductor layer. The first contact layer 140 may be positioned at the center of the contact hole 134H.

The first contact layer 140 can transmit an electrical signal to a semiconductor light emitting device 150a by connecting a first electrode through the opening 135. The first contact layer 140 can include a magnetic layer for assembling a semiconductor light emitting device.

Therefore, the embodiment has the technical effect of increasing the light emitting area area and improving light emitting efficiency as the first contact layer is positioned within the contact hole.

Also, in the embodiment, a second contact layer 142 may be disposed in the light emitting area 130. The second contact layers 142 may include a plurality of them, and may be disposed symmetrically with respect to the first contact layer 140, but are not limited thereto. The second contact layers 142 may then be connected to a second electrode to transmit an electrical signal to the semiconductor light emitting device. The plurality of second contact layers 142 may be respectively connected to a plurality of second electrodes, or may also be connected to a single second electrode. The second electrode may be a transparent electrode, such as ITO or IZO.

The second contact layer 142 may be connected to a second conductivity-type semiconductor layer of the semiconductor light emitting device, and the first contact layer 140 may be connected to a first conductivity-type semiconductor layer.

Also, the second contact layer 142 may be positioned higher than the first contact layer 140.

Meanwhile, the first contact layer 140 may be positioned inside the contact hole 134H, and the second contact layer 142 may be positioned outside the contact hole 134H. Accordingly, the second contact layer 142 may be positioned higher than the first contact layer 140. Accordingly, in the embodiment, the contact hole is positioned at the center of the semiconductor light emitting device, and since the first contact layer including the magnetic layer is disposed in the contact hole, the center of gravity may be concentrated at the center of the semiconductor light emitting device. Accordingly, the embodiment has the technical effect of ensuring uniform assembly force of the semiconductor light emitting device during self-assembly. Also, the embodiment has the technical effect of preventing the semiconductor light emitting device from tilting and moving toward the assembly hole during self-assembly, thereby improving the correct assembly rate.

FIG. 10 is a perspective view illustrating a pixel semiconductor light emitting device 150B according to a second embodiment. FIG. 10 may employ the technical features of FIG. 9. For example, a contact hole may be formed at the center of the semiconductor light emitting device, and a first contact layer may be disposed within the contact hole.

Hereinafter, the technical features of FIG. 10 will be described. Referring to FIG. 10, the upper portion of the semiconductor light emitting device 150B is a light emitting area 130, and a contact hole 134H may be formed at the center of the light emitting area 130.

Additionally, an opening extending horizontally from the contact hole 134H may be formed. The opening may include a first opening 135a and a second opening 135b. The first opening 135a and the second opening 135b may be disposed symmetrically with respect to the contact hole 134H, but are not limited thereto. As the contact hole 134H and the first and second openings 135a, 135b are formed, the light emitting area 130 may include a first light emitting area 130a and a second light emitting area 130b.

A first contact layer 140 may be placed within the contact hole 134H. The first contact layer 140 may include a magnetic layer for self-assembly. Also, the first contact layer 140 may be connected to a first electrode during a subsequent panel process to transmit an electrical signal to the semiconductor light emitting device. The first contact layer 140 may be electrically connected to the first electrode through the first opening 135a and the second opening 135b.

Therefore, the second embodiment has the technical effect of improving the assembly rate by concentrating the center of gravity of the semiconductor light emitting device at the center during self-assembly, as the first contact layer is positioned at the center of the semiconductor light emitting device.

Furthermore, since the first contact layer 140 is connected to the first electrode from both directions, there is a technical effect of improving the electrical signal processing speed. Furthermore, the second embodiment has a technical effect of improving the reliability of panel wiring connections, since the first contact layer 140 of the semiconductor light emitting device 150c is connected to the panel wiring from both directions during the panel process.

Furthermore, since the second embodiment has the first opening 135a and the second opening 135b symmetrically disposed with respect to the first contact layer 140, the balance of the semiconductor light emitting device within the fluid may be improved. Accordingly, the second embodiment has a technical effect of preventing the semiconductor light emitting device from tilting or flipping within the fluid, thereby improving the assembly rate.

Meanwhile, second electrodes 142a, 142b may be disposed on the first light emitting area 130a and the second light emitting area 130b, respectively. The second contact layer 142 may then be connected to the second electrode to transmit an electrical signal to the semiconductor light emitting device. The plurality of second contact layers 142a, 142b may be respectively connected to the plurality of second electrodes, or may be connected to a single second electrode. The second electrode may be a transparent electrode, such as ITO or IZO. Therefore, the second embodiment has a technical effect of preventing a decrease in luminous efficiency due to a decrease in the area of the light emitting area, as the second contact layer 142 disposed on the light emitting area 130 is connected to the transparent electrode.

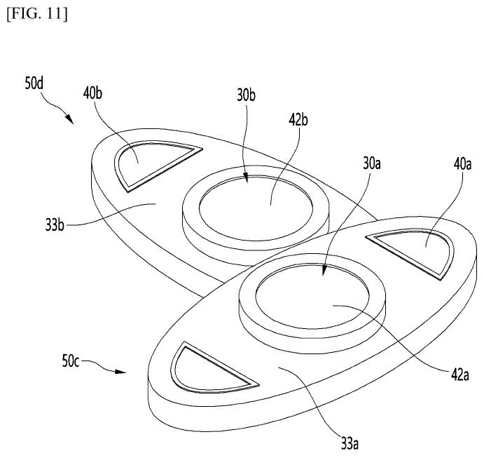

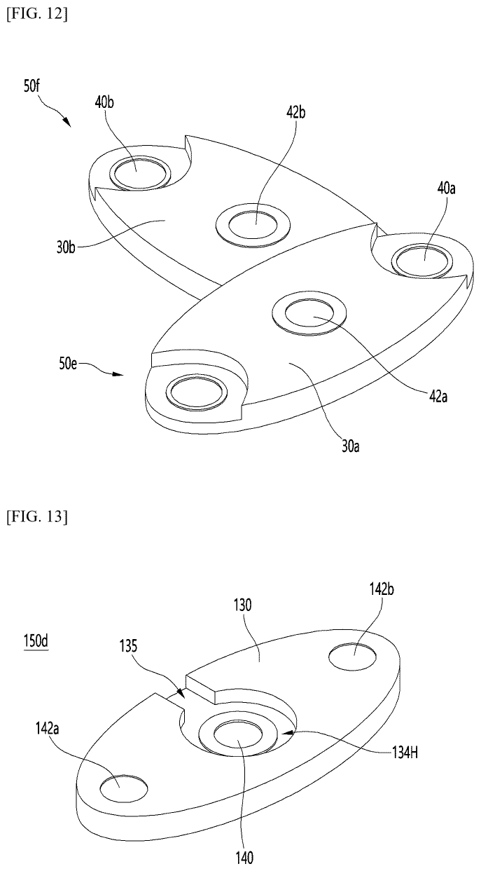

FIGS. 11 and 12 are perspective views of internally studied semiconductor light emitting devices. Referring to FIG. 11, the internally studied semiconductor light emitting devices (50c, 50d) may have an oval shape. Furthermore, the semiconductor light emitting devices (50c, 50d) may be semiconductor light emitting devices that emit blue and green light, respectively, but are not limited thereto. Furthermore, the semiconductor light emitting devices (50c, 50d) may be horizontal semiconductor light emitting devices.

The semiconductor light emitting devices (50c, 50d) may include a passivation layer, light emitting areas (30a, 30b), and a first contact layer (40a, 40b). The above light emitting area (30a, 30b) may have a second contact layer (42a, 42b) disposed thereon, and the second contact layer may be connected to a transparent electrode such as ITO or IZO.

Meanwhile, the area of the light emitting area (30a, 30b) may be small due to the first contact layer 140 and the passivation layer (33a, 33b), which may cause a problem of reduced light emitting efficiency.

Referring to FIG. 12, the semiconductor light emitting device (50e, 50f) may have a light emitting area (30a, 30b) formed on the upper surface of the semiconductor light emitting device, and a second contact layer (42a, 42b) may be disposed at the center of the light emitting area (30a, 30b). A groove may be formed in the outer region of the light emitting area (30a, 30b), and a first contact layer (40a, 40b) may be disposed within the groove. The first contact layer (40) may include a magnetic layer for self-assembly.

Meanwhile, since the first contact layer (40a, 40b) of the semiconductor light emitting device (50e, 50f) is disposed in the outer region of the semiconductor light emitting device, assembly defects may occur due to misalignment of the light emitting device during self-assembly.

Hereinafter, the technical features of an embodiment for solving the above-described problem will be described.

FIG. 13 is a perspective view of a semiconductor light emitting device for pixels according to a third embodiment. Referring to FIG. 13, the semiconductor light emitting device 150c of the third embodiment may have an oval shape. The semiconductor light emitting device 150c of the embodiment may be a semiconductor light emitting device that emits blue or green light, but is not limited thereto. Also, the semiconductor light emitting device according to the third embodiment may have a structure of a horizontal semiconductor light emitting device, but is not limited thereto.

A semiconductor light emitting device 150c for pixels according to an embodiment may include a first conductivity-type semiconductor layer, an active layer, a second conductivity-type semiconductor layer, a passivation layer, a first contact layer, a second contact layer, an opening, and a contact hole.

In an embodiment, an upper region of the semiconductor light emitting device 150c may be a light emitting area 130. Meanwhile, a contact hole 134H may be formed within the light emitting area 130. The contact hole 134H may be formed at the center of the semiconductor light emitting device 150d. Also, the contact hole 134H may include an opening 135 that extends horizontally and is connected to the exterior of the semiconductor light emitting device.

Meanwhile, a first contact layer 140 may be positioned within the contact hole 134H. The first contact layer 140 may be connected to a first electrode through the opening 135 to transmit an electrical signal to the semiconductor light emitting device 150d. The first contact layer 140 may include a magnetic layer for self-assembly of the semiconductor light emitting device.

Meanwhile, internally, research is being conducted on manufacturing RGB semiconductor light emitting devices in different shapes for simultaneous assembly. Accordingly, semiconductor light emitting devices have been manufactured in circular or oval shapes. However, research is being conducted on the issue of different behavioral characteristics and assembly rates depending on the chip shape. Furthermore, research is being conducted on horizontally structured oval semiconductor light emitting devices, which are prone to unstable center of gravity and increased difficulty in the electrode connection process.

On the other hand, in the third embodiment, since the first contact layer 140 including the magnetic layer is positioned within the contact hole, the center of gravity may be concentrated at the center of the semiconductor light emitting device. Accordingly, the third embodiment has the technical effect of ensuring uniform assembly force of the semiconductor light emitting device during self-assembly. In particular, since the first contact layer including the magnetic layer is positioned at the center of the oval semiconductor light emitting device, the problem of the semiconductor light emitting device tilting and moving toward the assembly hole during self-assembly is prevented, thereby improving the accuracy of assembly.

Furthermore, the third embodiment has the technical effect of reducing the difficulty and shortening the process time in the subsequent panel process by unifying the position of the first contact layer even when the external shapes of the circular and oval semiconductor light emitting devices are different.

Also, in the third embodiment, a second contact layer 142 may be disposed in the light emitting area 130. The second contact layers 142 may include a plurality of them, and may be disposed symmetrically with respect to the first contact layer 140, but are not limited thereto. The second contact layers 142 may then be connected to a second electrode to transmit an electrical signal to a semiconductor light emitting device. The plurality of second contact layers 142 may be respectively connected to a plurality of second electrodes, or may also be connected to a single second electrode. The second electrode may be a transparent electrode such as ITO or IZO. Therefore, the third embodiment has a technical effect of preventing a decrease in light emitting efficiency due to a decrease in the area of the light emitting area as the second contact layers 142 disposed on the light emitting area 130 are connected to the transparent electrode.

The second contact layer 142a, 142b may be connected to a second conductivity-type semiconductor layer of a semiconductor light emitting device, and the first contact layer 140 may be connected to a first conductivity-type semiconductor layer. Also, the second contact layer 142 may be positioned higher than the first contact layer 140.

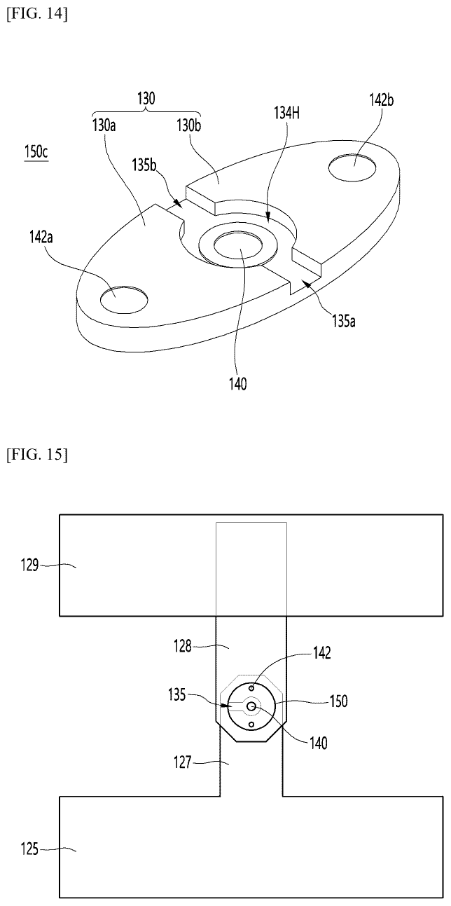

FIG. 14 is a perspective view of a pixel semiconductor light emitting device 150c according to a fourth embodiment. The fourth embodiment may employ the technical features of the third embodiment. For example, in the fourth embodiment, since the first contact layer including the magnetic layer is positioned within the contact hole, the center of gravity may be concentrated at the center of the semiconductor light emitting device. Accordingly, the first embodiment has the technical effect of ensuring uniform assembly force of the semiconductor light emitting device during self-assembly.

Hereinafter, the technical features of the fourth embodiment will be described.

Referring to FIG. 14, the upper portion of the semiconductor light emitting device 150c is a light emitting area 130, and a contact hole 134H may be formed at the center of the light emitting area 130.

Also, an opening extending horizontally from the contact hole 134H may be formed. The opening may include a first opening 135a and a second opening 135b. The first opening 135a and the second opening 135b may be disposed symmetrically with respect to the contact hole 134H, but are not limited thereto. As the contact hole 134H and the first and second openings 135a, 135b are formed, the light emitting area 130 may be separated into a first light emitting area 130a and a second light emitting area 130b.

Also, a first contact layer 140 may be disposed within the contact hole 134H. The first contact layer 140 may be connected to the first electrode through the first opening 135a and the second opening 135b to transmit an electrical signal to the semiconductor light emitting device.

Therefore, the fourth embodiment has the technical effect of improving the electrical signal processing speed as the first contact layer 140 is connected to the first electrode in both directions. Also, the fourth embodiment has the technical effect of improving the reliability of the panel wiring connection as the first contact layer 140 of the semiconductor light emitting device 150c is connected to the panel wiring in both directions during the panel process.

Furthermore, in the fourth embodiment, the first opening 135a and the second opening 135b are disposed symmetrically with respect to the first contact layer 140, thereby improving the balance of the semiconductor light emitting device within the fluid. Accordingly, the fourth embodiment has the technical effect of preventing the semiconductor light emitting device from tilting or flipping within the fluid, thereby improving the assembly rate.

FIG. 15 is a conceptual diagram illustrating electrode connections of a pixel semiconductor light emitting device. Referring to FIG. 15, the semiconductor light emitting device 150 of FIG. 15 may be a pixel semiconductor light emitting device according to the first to fourth embodiments.

The semiconductor light emitting device of the embodiment includes a first contact layer 140 and a second contact layer 142, and the second contact layer 142 may be positioned higher than the first contact layer 140. The first contact layer 140 may be an n-type contact layer and the second contact layer 142 may be a p-type contact layer, but is not limited thereto.

Meanwhile, the first contact layer 140 may be electrically connected to a first electrode 127. The first electrode 127 may be connected to a first bus electrode 125. The first electrode 127 may be connected to the first contact layer 140 through an opening 135 of the semiconductor light emitting device.

Also, the second electrode 128 connected to the second bus electrode 129 may be electrically connected to the second contact layer 142 of the semiconductor light emitting device 150. The second electrode 128 may be disposed to cover the upper surface of the semiconductor light emitting device 150. The second electrode 128 may be formed by including at least one of light-transmitting materials such as ITO (indium tin oxide), IAZO (indium aluminum zinc oxide), IZO (indium zinc oxide), IZTO (indium zinc tin oxide), IGZO (indium gallium zinc oxide), IGTO (indium gallium tin oxide), AZO (aluminum zinc oxide), ATO (antimony tin oxide), GZO (gallium zinc oxide), IZON (IZO Nitride), AGZO (Al-Ga ZnO), and IGZO (In-Ga ZnO), but is not limited to these materials.

The second electrode 128 may be positioned higher than the first electrode 127.

Therefore, the embodiment has a technical effect that the area of the light emitting area can be increased and the light emitting efficiency can be improved as the first electrode 127 is connected to the first contact layer 140 of the semiconductor light emitting device 150 and the second electrode 128 is connected to the second contact layer 142.

Also, the first contact layer 140 may be positioned at the center of the semiconductor light emitting device 150, and the second contact layer 142 may be positioned higher than the first contact layer 140. Accordingly, the pixel semiconductor light emitting devices of the first to fourth embodiments have a technical effect that the panel wiring process is the same even if the external shape of the semiconductor light emitting device is different, thereby reducing the difficulty of the wiring process and shortening the process time.

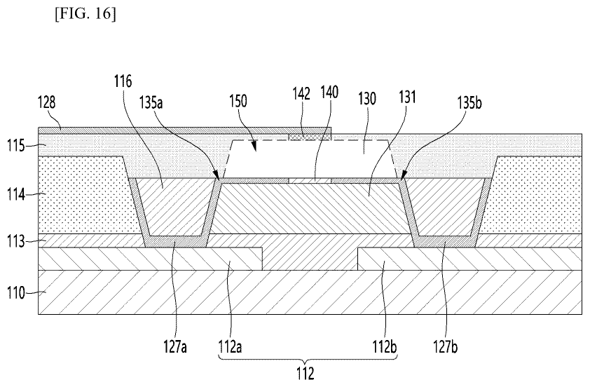

FIG. 16 is a cross-sectional view of a display device including a pixel semiconductor light emitting device according to a fifth embodiment. In the display device of the fifth embodiment, the pixel semiconductor light emitting devices of the first to fourth embodiments may be employed.

Referring to FIG. 16, the display device including the pixel semiconductor light emitting device according to the fifth embodiment may include a substrate 110, an assembly wiring 112, a partition wall 114, and a semiconductor light emitting device 150.

In detail, an assembly wiring 112 may be disposed on a substrate 110. The assembly wiring 112 may include a first assembly wiring 112a and a second assembly wiring 112b that are disposed spaced apart from each other. Different power sources may be applied as alternating current to the first assembly wiring 112a and the second assembly wiring 112b, and a DEP force may be formed to allow the semiconductor light emitting device 150 to be assembled into the assembly hole. The assembly wiring 112 may then function as a pixel electrode in a panel.

An insulating layer 113 may be disposed on the assembly wiring 112. Also, an assembly partition wall 114 having an assembly hole may be disposed on the insulating layer 113. A semiconductor light emitting device 150 may be disposed within the assembly hole. The semiconductor light emitting device 150 may include a first conductivity-type semiconductor layer 131 and a first contact layer 140 disposed on the first conductivity-type semiconductor layer 131. In FIG. 16, the first contact layer 140 is illustrated as being positioned higher than the first conductivity-type semiconductor layer 131, but the heights of the upper surfaces of the first contact layer 140 and the first conductivity-type semiconductor layer 131 may correspond.

Also, the semiconductor light emitting device 150 may include a light emitting area 130 having an active layer and a second conductivity-type semiconductor layer. A second contact layer 142 may be disposed on the light emitting area 130. The height of the upper surface of the second contact layer 142 may correspond to the height of the upper surface of the light emitting area 130.

In the display device of the fifth embodiment, the electrode process may be a self-aligned electrode process. Specifically, after forming first electrodes 127a, 127b on the semiconductor light emitting device 150 and the assembly barrier 114, an organic film 116 may be formed thereon. The first electrode may be connected to the first contact layer 140 of the semiconductor light emitting device 150 through the first opening 135a, 135b.

Next, after the organic film 116 is ashed to the bottom of the active layer of the semiconductor light emitting device 150, the first electrodes 127a, 127b may be formed as shown in FIG. 16 through metal etching. The first electrodes 127a, 127b may be positioned lower than the active layer of the semiconductor light emitting device.

The first contact layer 140 may be electrically connected to the first electrodes 127a, 127b through the first opening 135a and the second opening 135b. Also, the first electrodes 127a, 127b may be connected to the assembly wiring 112. The above assembly wiring 112 can assemble a semiconductor light emitting device into an assembly hole by applying an AC power of opposite charge during self-assembly to generate a DEP force, but after assembly, an electric power of the same charge may be applied to transmit an electric signal to the semiconductor light emitting device 150.

Therefore, the fifth embodiment has the technical effect of transmitting an electrical signal to a horizontal semiconductor light emitting device through a side wiring. Also, the fifth embodiment has the technical effect of enabling the assembly wiring to be utilized as a pixel wiring.

Next, a planarization layer 115 may be disposed to cover the semiconductor light emitting device 150 and the assembly barrier, and a second electrode 128 may be disposed on the planarization layer. The second electrode 128 may be electrically connected to the second contact layer 142 of the semiconductor light emitting device 150. The second electrode 128 may cover the entire upper surface of the semiconductor light emitting device 150. Also, the second contact layer 142 and the second electrode 128 may be transparent electrodes.

Therefore, the fifth embodiment has the technical effect of increasing the area of the light emitting area, thereby improving light emitting efficiency, by disposing the first contact layer in the center of the contact hole of the semiconductor light emitting device in a horizontal semiconductor light emitting device. Furthermore, the fifth embodiment has the special technical effect of preventing misalignment of the semiconductor light emitting device during self-assembly, thereby improving the assembly rate, since the first contact layer including the magnetic layer is disposed in the center of the contact hole of the semiconductor light emitting device.

The pixel semiconductor light emitting device according to the embodiment and the display device including the same have the technical effect of improving light emitting efficiency.

For example, the embodiment can improve light emitting efficiency by forming the first contact layer within the contact hole of the horizontal semiconductor light emitting device, thereby increasing the area of the light emitting area.

Also, the embodiment has the technical effect of improving the assembly rate of a semiconductor light emitting device for pixels.

For example, the embodiment can dispose a first contact layer including a magnetic layer at the center of a semiconductor light emitting device to concentrate the center of gravity at the center of the semiconductor light emitting device and prevent the semiconductor light emitting device from being biased during self-assembly.

For example, the embodiment can improve the balance of the semiconductor light emitting device within a fluid by symmetrically disposing the first opening and the second opening with respect to the first contact layer. Accordingly, the phenomenon of the light emitting device tilting or flipping within the fluid can be prevented, thereby having the technical effect of improving the assembly rate.

Also, the embodiment has the technical effect of ensuring uniform assembly force of semiconductor light emitting devices during self-assembly.

For example, the embodiment has a structure in which the first contact layer is located at the center of the semiconductor light emitting device and the second contact layer is located at the periphery, even if the external shapes of circular and oval semiconductor light emitting devices are different, thereby ensuring uniform assembly force.

Also, the embodiment has the technical effect of improving the reliability of panel wiring connections in a display device.

For example, the embodiment can improve the reliability of panel wiring connections by connecting the first contact layer to the first electrode in both directions.

Furthermore, the embodiment has the technical effect of reducing the difficulty and process time of the wiring process by performing the panel wiring process in the same manner even when the external appearances of the semiconductor light emitting devices are different.

Furthermore, the embodiment has the technical effect of uniformly controlling the behavioral characteristics of semiconductor light emitting devices during self-assembly in a fluid.

Although the present invention has been described above with reference to embodiments thereof, it will be readily understood by those skilled in the art that various modifications and changes to the present invention may be made without departing from the spirit and scope of the present invention as set forth in the following claims.

### EXPLANATION OF CITED REFERENCE

110: Substrate
112: Assembly wiring
112a: First assembly wiring
112b: Second assembly wiring
113: Insulating layer
114: Assembly partition wall
115: Planarization layer
116: Organic film
125: First bus electrode
127: First electrode
128: Second electrode
129: Second bus electrode
130: Light emitting area
130a: First light emitting area
130b: Second light emitting area
131: First conductivity-type semiconductor layer
133: Passivation layer
134H: Contact hole
135: Opening
135a: First opening
135b: Second opening
140: First contact layer
140a: First-first contact layer
140b: First-second contact layer
42, 142: Second contact layer
142a: Second-first contact layer
142b: Second-second contact layer

1. A semiconductor light emitting device for pixels comprising:
a light emitting structure comprising a first conductivity-type semiconductor layer, an active layer, and a second conductivity-type semiconductor layer;
a contact hole disposed in the light emitting structure, and configured to penetrate the second conductivity-type semiconductor layer and the active area to expose a portion of the first conductivity-type semiconductor layer;
a first contact layer disposed in the contact hole and positioned lower than the second conductivity-type semiconductor layer; and
a second contact layer disposed on the light emitting structure and electrically connected to the second conductivity-type semiconductor layer,
wherein the contact hole comprises an opening to extend in a horizontal direction.

2. (canceled)

3. The semiconductor light emitting device for pixels according to claim 1, wherein the opening comprises a plurality of openings.

4. The semiconductor light emitting device for pixels according to claim 3, wherein the light emitting structure comprises a plurality of light emitting areas by the plurality of openings.

5. The semiconductor light emitting device for pixels according to claim 1, wherein the first contact layer comprises a magnetic layer.

6. The semiconductor light emitting device for pixels according to claim 5, wherein the first contact layer is located at the center of the light emitting structure.

7. The semiconductor light emitting device for pixels according to claim 1, wherein the second contact layer is positioned higher than the first contact layer.

8. The semiconductor light emitting device for pixels according to claim 1, wherein the second contact layer comprises a plurality of second contact layers, and
wherein the plurality of second contact layers are disposed symmetrically with respect to the first contact hole.

9. The semiconductor light emitting device for pixels according to claim 1, wherein a planar shape of the light emitting structure is circular.

10. The semiconductor light emitting device for pixels according to claim 1, wherein a planar shape of the light emitting structure is oval.

11. (canceled)

12. The semiconductor light emitting device for pixels according to claim 3, wherein the plurality of openings are disposed symmetrically with respect to the contact hole.

13. The semiconductor light emitting device for pixels according to claim 4, wherein the second contact layer is disposed in each of the plurality of light emitting areas.

14. The semiconductor light emitting device for pixels according to claim 1, wherein the opening is located at the same height as the contact hole.

15. The semiconductor light emitting device for pixels according to claim 1, wherein the second contact layer is surrounded by the light emitting area.

16. The semiconductor light emitting device for pixels according to claim 1, wherein the opening is configured to overlap the first contact layer in the horizontal direction.

17. The semiconductor light emitting device for pixels according to claim 1, wherein the opening is configured not to overlap horizontally with the second contact layer.

18. The semiconductor light emitting device for pixels according to claim 1, wherein a width of the opening is smaller than a diameter of the contact hole.

19. A display device including a semiconductor light emitting device comprising:
a substrate;
a plurality of assembly wirings spaced apart from each other on the substrate;
a barrier wall disposed on the plurality of assembly wirings and having an assembly hole; and
a semiconductor light emitting device disposed in the assembly hole,
wherein the semiconductor light emitting device comprises a light emitting structure comprising a first conductivity-type semiconductor layer, an active layer, and a second conductivity-type semiconductor layer;
a contact hole disposed in the light emitting structure, and configured to penetrate the second conductivity-type semiconductor layer and the active area to expose a portion of the first conductivity-type semiconductor layer;
a first contact layer disposed in the contact hole and positioned lower than the second conductivity-type semiconductor layer; and
a second contact layer disposed on the light emitting structure and electrically connected to the second conductivity-type semiconductor layer, and
wherein the contact hole comprises an opening to extend in a horizontal direction.

20. The display device according to claim 19, further comprising a first electrode electrically connected to the first contact layer in the horizontal direction through the opening.

21. The display device according to claim 20, further comprising a second electrode electrically connected to the second contact layer,
wherein the second electrode is configured not to overlap with the first electrode in a vertical direction.

22. The display device according to claim 19, wherein a planar shape of the light emitting structure is oval.
